(19) United States
(12) Patent Application Publication
(10) Pub. No.: US 2017/0097003 A1
(43) Pub. Date: Apr. 6, 2017

(54) HYBRID FAN ARRANGEMENT

(71) Applicant: Quanta Computer Inc., Taoyuan City (TW)

(72) Inventors: Chao-Jung CHEN, Taoyuan City (TW); Yi-Chieh CHEN, Taoyuan City (TW); Chi-Fu CHEN, Taoyuan City (TW)

(21) Appl. No.: 14/873,472

(22) Filed: Oct. 2, 2015

(51) Int. Cl. F04D 25/08; G06F 1/20; F04D 29/52; H05K 7/20; F04D 19/00; F04D 27/00

(52) U.S. Cl. CPC F04D 25/08; F04D 19/002; F04D 27/00; F04D 29/522; H05K 7/20727; G06F 1/20

(57) ABSTRACT

A server rack assembly having a housing configured to receive at least one server sled. A first fan associated with the housing, the first fan having a first size and a second fan having a second size. The first fan and the second fan are operated at different speeds to maintain a predetermined temperature in the server rack assembly.

### FIELD

The subject matter herein generally relates to fan arrangements. More specifically, the subject matter herein relates to fan arrangements for server rack assemblies.

### BACKGROUND

Known server rack assemblies having cooling systems to maintain predetermined temperatures within the server rack. Present cooling systems use fans to induce an airflow and remove heat from the server rack assembly. But, in order to provide adequate cooling, the fans operate high revolutions per minute (rpm) causing noise, increased power use, and vibration.

### BRIEF DESCRIPTION OF THE DRAWINGS

Implementations of the present technology will now be described, by way of example only, with reference to the attached figures, wherein:

FIG. 1 is an isometric view of an exemplary embodiment of a housing of a server rack assembly;

FIG. 2 is a front view of an exemplary embodiment of a server rack assembly;

FIG. 3 is a rear view of an exemplary embodiment of the server rack assembly of FIG. 2;

FIG. 4 is a top cross section view of an exemplary embodiment of a housing of the server rack assembly of FIG. 3; and

FIG. 5 is a flow chart of an exemplary method of a server rack assembly.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

While the disclosure is discussed with reference to the illustrated embodiments, the hybrid fan arrangement and the arrangement of a first fan and a second fan, and their respective set of fans, within a server sled can be varied as would be appreciated by one of ordinary skill in the art.

Further to the background set forth above, one of the problems is the use of a same size of large fan, thus when trying to achieve a predetermined temperature or keep server rack assemblies at a predetermined temperature, the large fans are operated at a high revolutions per minute (rpm) wasting energy.

Traditional server sled utilize a plurality of large fans operating at a high rpm to maintain a predetermined temperature within the server sled and server rack assembly within which the server sled is received. The use of large fans at high rpms is energy intensive and inefficient. The present disclosure is focused on improving the energy usage by implementing large fans in conjunction with small fans, allowing the large fans to be operated at a lower rpm than traditionally server sleds while operating the small fans at a higher rpm to achieve the predetermined temperature. The aggregation of large fans and small fans can reduce the energy required to cool and maintain a predetermined temperature. Energy savings up to 50% can be realized by utilizing such an aggregation of large and small fans. A control system can also be implemented with the large and small fans allowing their respective rpms to be adjusted as needed based on the temperature within the server sled and the necessary cooling capacity. The server rack assembly can have a housing configured to receive at least one server rack sled. The housing can have a first fan having a first size associated therewith and a second fan having a second size. The first fan and the second fan can be operated to reduce the temperature of the server rack assembly by exhausting heat generated by the at least one server rack sled. The first fan and the second fan can be operated at different speeds to maintain a predetermined temperature in the server rack assembly. The first fan can be part of a first set of fans, and the second fan can be part of a second set of fans. The first set of fans can be larger than the second set of fans and the first set of fans can operate at a slower revolutions per minute (rpm) than the second set of fans. The first set of fans and the second set of fans can each form an array of rows and columns, each row and column of each set of fans can be capable of being operated at a different speed.

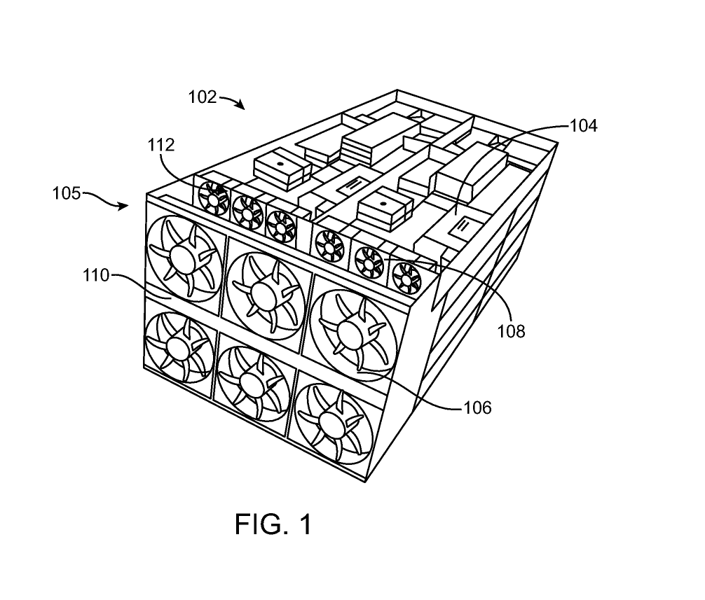

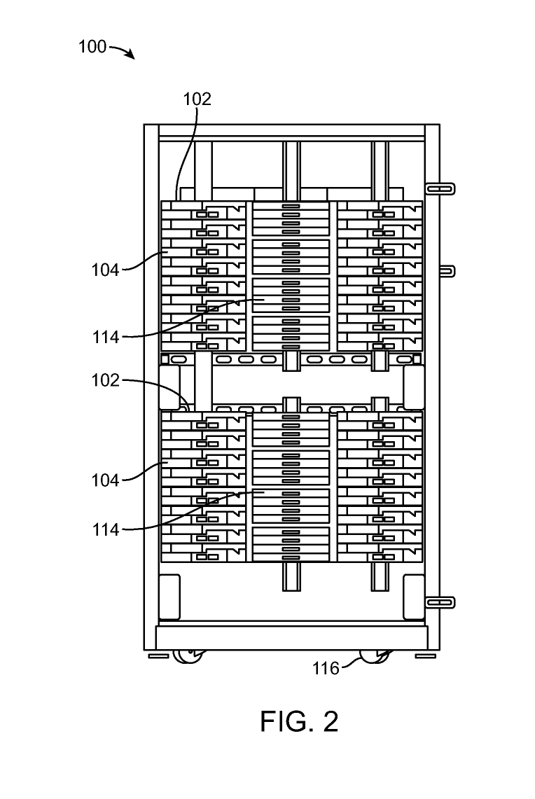

FIG. 1 illustrates an isometric view of an exemplary embodiment of a housing of a server rack assembly. A housing 102 can be received within a server rack assembly 100 (shown in FIG. 2). The housing can be formed from metal, plastic, composite, or a combination thereof and configured to support and secure the housing 102 within the server rack assembly 100. The housing 102 can receive at least one server sled 104. The housing 102 can be configured to receive a cooling system 105 to reduce heat generated by the at least one server sled 104. The cooling system 105 can have a first fan 106 and a second fan 108. The first fan 106 can be larger than the second fan 108. The first fan 106 can operate a first speed and the second fan 108 can operate at a second speed. The first speed, in revolutions per minute (rpm), can be slower than the second speed. In at least one embodiment, the first speed is about 3,000 rpm and the second speed is about 5,800 rpm. In alternative embodiments, the first speed can be between 800 rpm and 7,000 rpm and the second speed can be between 1,200 rpm and 20,000 rpm. Other revolutions per minutes outside these ranges are contemplated.

The first fan 106 and the second fan 108 operating in tandem can reduce the collective power usage of the cooling system 105 to maintain a predetermined temperature within the housing 102. The cooling system 105 can reduce the power usage by operating the larger first fan 106 at a slower speed and operating the second, smaller fan 108 at a faster speed, thus still maintaining the predetermined temperature. In at least one embodiment, the first fan 106 is a 140×140 mm fan and the second fan 108 is a 60×60 mm fan. In other embodiments, the size of the first fan 106 and the second fan 108 can be varied based on the specifications of the server rack assembly 100 and the housing 102.

The cooling system 105 employing a first fan 106 and a second fan 108 can also reduce the acoustic signature and vibration of the server rack assembly 100 and cooling system 105 because the larger first fan 106 can operate at a slower speed.

In at least one embodiment, the first fan 106 and the second fan 108 can each be independently angularly adjustable to improve efficiency of the induced airflow of the cooling system 105.

The first fan 106 can be a part of a first set of fans 110 and the second fan can be part of a second set of fans 112. The first set of fans 110 can have at least two fans and the second set of fans 112 can have at least two fans. In at least one embodiment, the first set of fans 110 can have between 4 and 8 fans, and the second set of fans 112 can have between 1 and 30 fans. The first set of fans 110 can be arranged in an array of rows and columns and the second set of fans 112 can also be arranged in an array of rows and columns. The first fan 106, or first set of fans 110, can be associated with a rear side of the housing 102 and the second fan 108, or second set of fans 112, can be inside the housing 102 and located close to the rear side, middle, or a front side of the housing 102. In at least one embodiment, the first set of fans 110 can be coupled to the rear of the housing 102 and the second set of fans 112 can be coupled to the rear of the at least one sled 104. In other embodiments, the first set of fans 110 can be coupled to the rear of the housing 102 and the second set of fans 112 can be coupled to the side of the housing 102. In yet another embodiment, the first set of fans 110 can be coupled to the rear of the housing 102 and the second set of fans 112 can be coupled to the housing 102 between the rear of the at least one sled 104 and the first set of fans 110.

In at least one embodiment, the first set of fans 110 and the second set of fans 112 can be in substantial alignment. The substantial alignment can allow the induced air flow to move in a single direction between the first set of fans 110 and the second set of fans 112.

As can be appreciated in FIG. 1, the first set of fans 110 has six fans and each server sled 104 can have three second fans 108. The first set of fans 110 is arranged in an array of two first fans 106 per column and three first fans 106 per row. The first set of fans 110 can be controlled individually, by column, or by row. In at least one embodiment, to maintain a predetermined temperature each first fan 106 can be 140×140×38 mm operating at 3,050 rpm drawing 8.6 W and each second fan 108 can be a 60×60×38 mm fan operating at 5,800 rpm drawing 2 W. The aggregate power for the cooling system is 111.6 W. In a similar embodiment employing only a first set of fans, the first set of fans operates at 5,800 rpm to maintain the predetermined temperature and each fan draws 25.1 W for an aggregate cooling system power of 150.6 W. The cooling system 105 maintain a predetermined temperature employing a first set of fans 110 and a second set of fans 112 reduces power consumption as opposed to a cooling system employing on a first set of fans.

In at least one embodiment, each of the first fans 106 of the first set of fans 110 can be controlled individually and operate at a different speed relative to one another. In other embodiments, each row of the first set of fans 110 can operate at a different speed relative to the other rows. In yet other embodiment, each column of the first set of fans 110 can operate at a different speed relative to the other columns.

In the illustrated embodiments, each of the first fans 106 are disposed at the rear of the housing 102 and each of the second fans 108 are disposed at the rear of the server sled 104. The second fans 108 being in substantial alignment with the first fans 106. In other embodiments, the first fans 106 and second fans 108 can disposed throughout the housing 102 and server sled 104 without regard to alignment. The first fans 106 and the second fans 108 can be on any where within or attached to the housing 102, server sled 104, and/or coupled a specific component. The operating speed (rpm) of each first fan 106 and each second fan 108 can be adjusted individually by a rack management controller 114 (shown in FIG. 2) to cooling of the server sled 104 and reduce power consumption.

As can further be appreciated in FIG. 1, the housing 102 has two server sleds 104 in a side-by-side arrangement forming a row of six second fans 108. The housing 102 has ten server sleds 104, arranged in two columns of five server sleds 104 each. In this embodiment, the second set of fans 112 comprises 30 second fans 108, five rows of six second fans 108. Each server sled can have three second fans 108 and the three second fans 108 associated the server sled 104 can be controlled individually with respect to the second set of fans 112.

FIG. 2 illustrates a front view of an exemplary embodiment of a server rack assembly. The server rack assembly 100 can have one or more housings 102. The housing 102 can be coupled to the server rack assembly 100, or the housing 102 can be integrally formed within the server rack assembly 100. The housing 102 can removably receive at least one server sled 104. In at least one embodiment, the at least one server sled 104 can be a plurality of server sleds 104 can be received within the housing 102. The plurality of server sleds 104 can be arranged horizontally or vertically within the housing 102.

As can be appreciated in FIG. 2, the plurality of sleds 104 are substantially equal to the width of the housing 102, and arranged horizontally, one stacked on top of the other. In alternative embodiments, the server sleds 104 can be arranged horizontally in columns and rows, such that each row has more than one server sled 104 and each column has more than one server sled 104. As illustrated in FIG. 1, the server sleds 104 can be arranged in a side-by-side arrangement with two server sleds 104 per row and five rows.

As can further be appreciated in FIG. 2, the server rack assembly 100 can have two housings 102 received therein. The housings 102 can be separate and independent of each other. Each housing 102 can receive at least one server sled 104. In at least one embodiment, the two housings 102 can be arranged substantially vertically, one on top of the other. The two housings 102 can be substantially identical, each capable of receiving the same number of server sleds 104 in substantially the same arrangement. In another embodiment, each housing 102 can receive at least one server sleds 104 in different arrangements. In yet other embodiments, the server rack assembly 100 can have two housings arranged side-by-side, thereby lowering the overall height of the server rack assembly 100.

The server rack assembly 100 and housing 102 can have a rack management controller 114 having a plurality of sensors (not shown). The sensors can be distributed throughout the housing 102 and the server rack assembly 100. In other embodiments, the sensors can be strategically placed within the housing 102 and the server rack assembly 100. The sensors can provide localized temperature data and thus control the cooling system 105 to evaluate the appropriate combination of fan size and fan speed to reduce the temperature based on the sensors in an energy efficient manner. The rack management controller 114 can use the sensors to determine the temperature within the housing 102 and server rack assembly 100 and adjust the speed of the first fan 106, the second fan 108, or their associated first set of fans 110 and second set of fans 112 as necessary. The rack management controller 114 can optimize the efficiency of the cooling system 105 by increasing or decreasing the speed of the respective fans to maintain a predetermined temperature. In at least one embodiment, the first set of fans 110 and/or the second set of fans 112 can be arranged in an array of rows and columns, and the rack management controller 114 can adjust each row and column individually or can adjust the entire set of fans collective. In other embodiments, the first fans 106 and second fans 108 are distributed throughout the housing 102 and server sled 104 and the rack management controller 114 can receive data from the plurality of sensors (not shown) and adjust the operating speed of each fan individually to maintain the predetermined temperature while reducing power consumption. The rack management controller 114 can utilize data from the sensors along with the sensor location within the server rack assembly 100 to adjust the appropriate fans, include first fans 106, second fans 108, first set of fans 110, and/or second set of fans 112 to efficiently and effective maintain the predetermined temperature.

In at least one embodiment, the management controller 114 can be a microprocessor, microcontroller, or computer disposed within the server rack assembly 100. The microprocessor, microcontroller, or computer can run software to analyze the data received from the plurality of sensors and adjust the first set of fans 110 and second set of fans 112 accordingly to maintain the predetermined temperature while minimizing power usage. In other embodiments, the management controller can be computer, server, or similar located outside of the server rack assembly 100, and maintaining the predetermined temperature based on the plurality of sensors while minimizing power usage.

The first set of fans 110 and the second set of fans 112 can each include angular vectoring controlled by the management controller 114. The management controller 114 can utilize the plurality of sensors to determine portions of the server rack with a temperature greater than the predetermined temperature and vector additional first fan 106 and second fan 108 cooling to reduce the temperature in a particular portion of the sever sled 104, housing 102, or server rack assembly 100. In at least one embodiment, the plurality of sensors can provide localized data indicating the upper left portion of the server rack assembly 100 is above the predetermined temperature and the management controller 114 can utilize angular vectoring to allow nearby fans of the first set of fans 110 and the second set of fans 112 to increase airflow and reduce the temperature in the specific portion of the server rack assembly 100. In other embodiments, each fan of the first set of fans 110 and second set of fans 112 can be individually rotatable to allow directional cooling controlled by the management controller 114.

The server rack assembly 100 can further include at least two wheels 116. The wheels 116 can allow movement and positioning of the server rack assembly 100. In the illustrated embodiment, the server rack assembly 100 has four wheels 116, one positioned at each corner of the bottom surface of the server rack assembly 100. In other embodiments, the server rack assembly 100 can have any number of wheels 116 positioned at various points of the bottom surface to allow movement and positioning of the server rack assembly 100.

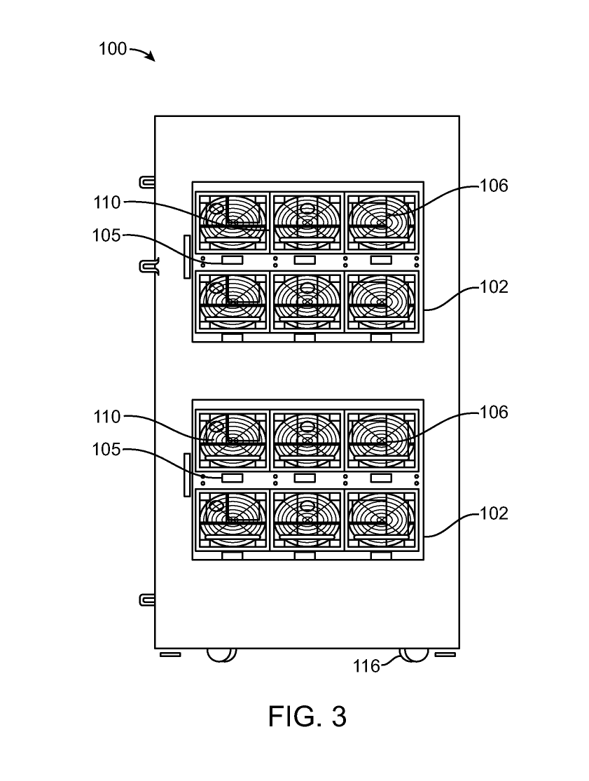

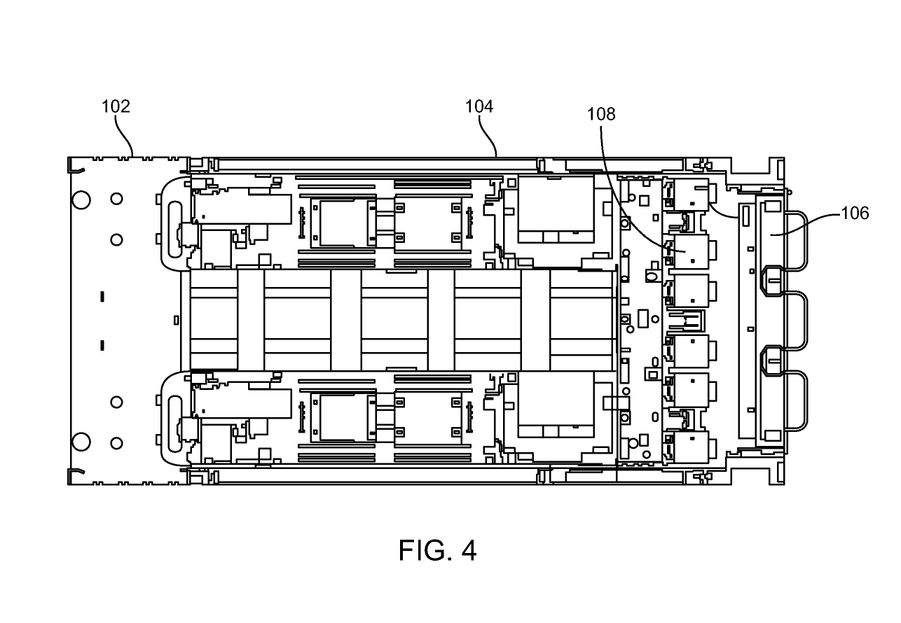

FIG. 3 illustrates a rear view of an exemplary embodiment of a server rack assembly of FIG. 2. The server rack assembly 100 can have a cooling system 105 integrated therewith to cool the at least one server sled 104 within the housing 102. The cooling system 105 can have a first fan 106. The first fan 106 can be a part of a first set of fans 110. The cooling system 105 can also include a second fan 108. The second fan 108 can be part of a second set of fans 112 (shown in FIG. 4). The first set of fans 110 and second set of fans 112 can collectively, or individually, induce an airflow to maintain a predetermined temperature. In at least one embodiment, the at least one first fan 106 is larger than the at least one second fan 108, and operates at lower speed, in revolutions per minute. As can be appreciated in FIG. 3, in each housing 102 the first set of fans 110 has six first fans 106 arranged in two rows, three first fans 106 in each row.

In at least one embodiment, the first fan(s) 106 can be easily removed from the housing 102 and server rack assembly 100. The first set of fans 110 can be coupled to the housing 102, or alternatively, to the server rack assembly 100. The first fan(s) 106 can be removed without the use of tools, allowing quick removal for service or performance reasons. The first fan(s) 106 are slidably coupled to the housing 102 using a tongue-groove arrangement. In another embodiment, the first fan(s) 106 are coupled to the housing 102 using thumb screws. In another embodiment, the first fan(s) 106 are coupled to the housing 102 using a snap-fit arrangement. In yet other embodiments, the first set of fans 110 can be decoupled from the housing 102 before individual fans 106 can be removed, added, or replaced.

FIG. 4 illustrates a cross section view of an exemplary embodiment of the server rack assembly of FIG. 2. The at least one server sled 104 received within the housing 102 of the server rack assembly 100 can have at least one second fan 108. The second fan 108 can be smaller than the first fans 106, and can operate at a faster speed. The second fan 108 can form a second set of fans 112, a portion of which can be appreciated in FIG. 4. The second set of fans 112 can be located at the rear of the server sled 104 and substantially aligned with the first set of fans 110. The substantial alignment can allow the induced airflow to be in substantially the same direction. For example in the illustrated embodiment, the first set of fans 110 and the second set of fans 112 are substantially aligned inducing airflow from the rear of the server rack assembly 100. The second set of fans 112 can be coupled to the rear of the server sled 104, to the housing 102, or to the server rack assembly 100.

The first fan(s) 106 and second fan(s) 108 can be size appropriately to induce an appropriate airflow to maintain a predetermined temperature device. The fan size and fan operating speed can be determined by the number of sever sleds 104 in each housing 102 and server rack assembly 100 along with the anticipated heat generated by each server sled. The second fan(s) 108 can be operated at a faster speed than the first fan(s) 106 allowing the cooling system 105 to maintain a predetermined temperature within the server rack assembly 100. In at least one embodiment, the first fan 106 can be operated at about 3,050 rpm and the second fan 108 can be operated at about 5,800 rpm. In at least one embodiment, the temperature inside the housing 102 is 150° F while the predetermined temperature is 140° F. The first set of fans 110 and the second set of fans 112 can increase their rpm to reduce the temperature inside the housing 102 to the predetermined temperature.

As can be appreciated in FIG. 4, the rear of the server sled 104 has six second fans 108 in substantial alignment with at least a portion of three first fans 106 coupled to the housing 102. The second fans 108 can induce an airflow to remove heat from the server sled 104 to maintain the predetermined temperature. The first fans 106 can work in conjunction with second fans 108 to induce the airflow to maintain the predetermined temperature. The first fans 106 can each have a size of 140×140×60 mm

The server rack assembly 100 and cooling system 105 can be configured to receive at least one first fan 106 and at least one second fan 108. In at least one embodiment, the cooling system 105 can have only the at least one first fan 106 or only the at least one second fan 108, or their associated first set of fans 110 or second set of fans 112. One of the first fan 106 or the second fan 108, or their associated first set of fans 110 and second set of fans 112, can be omitted when the cooling system 105 can maintain the predetermined temperature according to cooling system 105 and rack assembly power consumption.

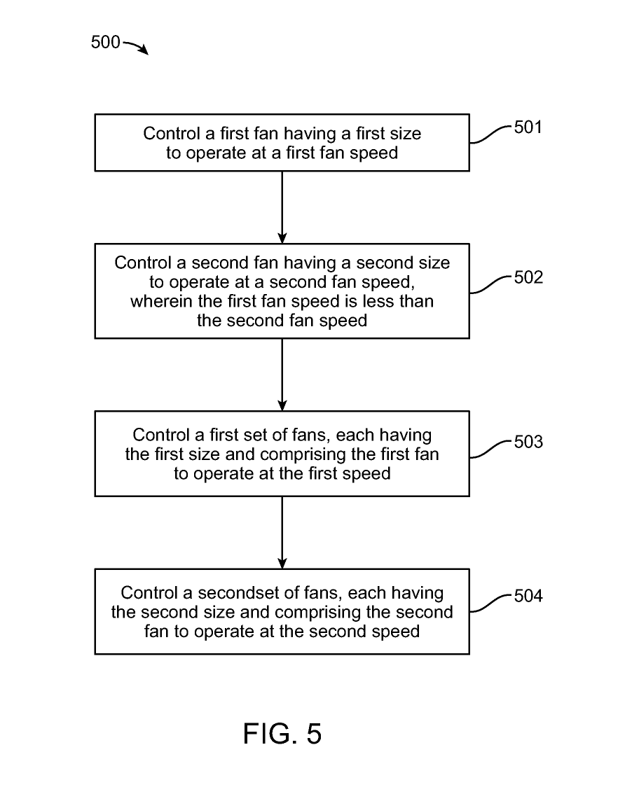

Referring to FIG. 5, a flowchart is presented in accordance with an example embodiment. The example method 500 is provided by way of example, as there are a variety of ways to carry out the method. The method 500 described below can be carried out using the configurations illustrated in FIGS. 1-4, for example, and various elements of these figures are referenced in explaining example method 500. Each block shown in FIG. 5 represents one or more processes, methods or subroutines, carried out in the example method 500. Furthermore, the illustrated order of blocks is illustrative only and the order of the blocks can change according to the present disclosure. Additional blocks may be added or fewer blocks may be utilized, without departing from this disclosure. The example method 500 can begin at block 501.

At block 501, the server rack assembly 100 can control a first fan 106 having a first size to operate at a first fan speed.

At block 502, the server rack assembly 100 can control a second fan 108 having a second fan having a second size to operate at a second fan speed. The first fan speed having a lower rpm than the second fan speed. The first size can be larger than the second size with the first fan speed being between 800 and 7,000 rpm and the second fan speed being between 1,200 and 20,000 rpm. In at least one embodiment, the first fan speed is about 3,000 rpm and the second fan speed is about 5,800 rpm.

At block 503, the server rack assembly 100 can control a first set of fans 110, each having the first size, to operate at the first fan speed.

At block 504, the server rack assembly 100 can control a second set of fans 112, each having the second size, to operate at the second fan speed.

It is believed the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiments of the disclosure.

What is claimed is:

1. A server rack assembly comprising:
a housing configured to receive at least one server sled;
a first fan associated with the housing, the first fan having a first size; and
a second fan having a second size,
wherein the first fan and the second fan are operated at different speeds to maintain a predetermined temperature in the server rack assembly.

2. The server rack assembly of claim 1, wherein the first size is larger than the second size.

3. The server rack assembly of claim 1, further comprising:
a first set of fans, of the first size, wherein the first fan is a part of the first set of fans.

4. The server rack assembly of claim 3, further comprising:
a second set of fans, of the second size, wherein the second fan is a part of the second set of fans.

5. The server rack assembly of claim 4, wherein the first set of fans comprises at least two fans and the second set of fans comprises at least two fans.

6. The server rack assembly of claim 4, wherein the first fan operates at a speed of between 800 and 7,000 revolutions per minute and the second fan operates at between 1,200 and 20,000 revolutions per minute.

7. The server rack assembly of claim 6, wherein the first set of fans is arranged in an array of rows and columns, each row and column capable of being operated at a different speed.

8. The server rack assembly of claim 6, wherein the second set of fans is arranged in an array of rows and columns, each row and column capable of being operated at a different speed.

9. The server rack assembly of claim 1, wherein the first fan and the second fan are arranged in substantial alignment.

10. The server rack assembly of claim 1, wherein the first fan is associated with a rear side of the housing and the second fan is inside the housing and located close to the rear side, middle or a front side of the housing.

11. A server rack housing comprising:
at least one server sled received in a housing;
a first fan associated with the housing, the first fan having a first size; and
a second fan associated with the at least one server sled having a second size,
wherein the first fan and the second fan are operated at different speeds to maintain a predetermined temperature in the server rack housing.

12. The server rack housing of claim 11, further comprising:
a first set of fans, of the first size, wherein the first fan is a part of the first set of fans.

13. The server rack housing of claim 12, further comprising:
a second set of fans, of the second size, wherein the second fan is a part of the second set of fans.

14. The server rack housing of claim 11, wherein the first set of fans is arranged in an array of rows and columns, each row and column capable of being operated at a different speed.

15. The server rack housing of claim 11, wherein the first fan and the second fan are arranged in substantial alignment.

16. The server rack housing of claim 11, wherein the first fan is associated with a rear side of the housing and the second fan is inside the housing and located close to the rear side, middle, or a front side of the housing.

17. A method of controlling a temperature in a server rack assembly, the method comprising:
controlling a first fan having a first size to operate at a first fan speed;
controlling a second fan having a second size to operate at a second fan speed, wherein the first fan speed is less than the second fan speed.

18. The method of claim 17, wherein the first size is larger than the second size.

19. The method of claim 17, wherein the first fan speed is between 800 and 7,000 revolutions per minute and the second fan speed is between 1,200 and 20,000 revolutions per minute.

20. The method of claim 17, further comprising:
controlling a first set of fans, each having the first size and comprising the first fan to operate at the first speed; and
controlling a second set of fans, each having a second size and comprising the second fan to operate at a second speed.
